(19) United States
(12) Patent Application Publication
(10) Pub. No.: US 2008/0311294 A1
(43) Pub. Date: Dec. 18, 2008

(54) VAPOR-PHASE GROWTH APPARATUS AND VAPOR-PHASE GROWTH METHOD

(76) Inventors: Hideki ITO, Shizuoka (JP); Hironobu HIRATA, Shizuoka (JP); Shinichi MITANI, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/139,172

(22) Filed: Jun. 13, 2008

(30) Foreign Application Priority Data
Jun. 15, 2007 (JP) 2007-158885
Jul. 25, 2007 (JP) 2007-192898

(51) Int. Cl. C23C 16/44; C23C 16/00

(52) U.S. Cl. 427/248.1; 118/728; 118/729

(57) ABSTRACT

There is provided a vapor-phase growth apparatus which reduces particle generation and an adhering material in epitaxial growth to make it easy to improve the productivity. The vapor-phase growth apparatus includes a gas supply port formed in a top portion of a reactor, a gas distribution plate arranged in the reactor, a discharge port formed in a bottom portion of the reactor, at a head portion and which covers a side wall of the reactor, an annular holder on which a semiconductor wafer is placed. A separation distance between the gas distribution plate and the annular holder is set such that a film forming gas which flows downward from the gas supply port through the gas distribution plate is in a laminar flow state on a surface of the semiconductor wafer or a surface of the annular holder.

### CROSS-REFERENCE TO RELATED APPLICATION

This application is based upon and claims the benefit of priority from Japanese Patent Applications No. 2007-158885, filed on Jun. 15, 2007 and No. 2007-192898, filed on Jul. 25, 2007 the entire contents of which are incorporated herein by reference.

### FIELD OF THE INVENTION

The present invention relates to a vapor-phase growth apparatus and a vapor-phase growth method. In particular, the present invention relates to a vapor-phase growth apparatus and a vapor-phase growth method which reduce particle generation and adhering materials in epitaxial growth of a semiconductor substrate to make it easy to improve the productivity of the semiconductor substrate.

### BACKGROUND OF THE INVENTION

For example, in manufacturing of a semiconductor device on which an ultrahigh-speed bipolar device, an ultrahigh-speed CMOS device, a power MOS transistor, and the like are formed, an epitaxial growth technique for a monocrystalline layer which is controlled in impurity concentration, film thickness, crystal defect, or the like is essential to improve the performance of the device.

An epitaxial growth apparatus grows a monocrystalline thin film on a surface of a semiconductor substrate such as a silicone wafer or a compound semiconductor wafer for use as a substrate of a semiconductor device. Such an epitaxial growth apparatus includes an epitaxial growth apparatus of a batch processing type which can process a large number of wafers at once and a single wafer processing type which processes wafers one by one. Since the batch processing epitaxial growth apparatus can process a large number of wafer substrates at once, the manufacturing cost of epitaxial wafers can be reduced with high productivity. On the other hand, the single-wafer-processing type epitaxial growth apparatus can cope with an increase in diameter of a wafer substrate and is good in uniformity of a film thickness or the like of the epitaxial growing layer.

In recent years, with a high integration density, a high performance, multifunctionalization, and the like of a semiconductor device using a silicon wafer, a silicone epitaxial wafer is expanded in application. For example, in manufacture of a semiconductor device on which a memory circuit composed of CMOS devices is mounted, a memory capacity is at, for example, a gigabit level. In order to secure the manufacturing yield, an epitaxial wafer is frequently used which has a silicon epitaxial layer having a thickness of, for example, about 10 μm and which is better in crystallinity than that of a bulk wafer. A so-called distorted silicon epitaxial layer having, for example, a silicon-germanium alloy layer which makes it easy to micro pattern elements and realize an ultra high-speed CMOS device is expected to be actually used. In a semiconductor device having a high-withstand-voltage device such as a power MOS transistor, an epitaxial wafer having a silicon epitaxial layer with a high specific resistance and a film thickness of, for example, about 50 to 100 μm.

In these circumstances, a diameter of a wafer increases, for example, 300 mmφ, a film thickness of an epitaxial growing layer must be uniformly controlled at high accuracy over a wafer surface, and the radio of the single-wafer-processing type epitaxial growth apparatus increases. However, as described above, since the single-wafer-processing type epitaxial growth apparatus cannot perform a batch process for wafers, the productivity of the epitaxial growth apparatus is in general lower than that of the batch processing epitaxial growth apparatus. As the single-wafer-processing type epitaxial growth apparatus, epitaxial growth apparatuses having various structures which increase epitaxial growth rates to improve productivity are disclosed (for example, see JP-A No. 11-67675(KOKAI)).

### SUMMARY OF THE INVENTION

With the single-wafer-processing type epitaxial growth apparatus disclosed in JP-A No. 11-67675, a growth rate of, for example, a silicon epitaxial layer can be increased to about 10 μm/min. In order to improve the productivity in manufacturing of an epitaxial wafer, an increase in yield of epitaxial layers and improvement of equipment utilization are important in addition to a growth rate of the epitaxial layer.

In this case, the yield of epitaxial layers, although depending on the performance of a semiconductor device to be manufactured, is considerably influenced by crystal defects, precipitates in crystal, a contaminated metal, particles, or the like of an epitaxial layer that is a monocrystalline layer of these elements, particles which are easily generated in epitaxial growth may be a factor of the crystal defects, the precipitates in crystal, or metal contamination. For this reason, a reduction of generated particles is a very important issue for the increase in yield.

An epitaxial layer is grown such that the temperature of a wafer placed on a predetermined position in a reactor is increased to a high temperature of 1000 to 1200° C. and a film-forming gas is supplied into the reactor to react the film forming gas on a surface of the wafer. However, the film forming gas partially reacts on an inner wall of the reactor to be precipitated to generate an adhering material, and the adhering material serves as a particle source. A part of the film forming gas or a reaction product thereof (also including a by-product) is precipitated in a space in the reactor to generate particles. For this purpose, in manufacture of an epitaxial wafer, a maintenance operation which removes particles or adhering materials consequently generated in the epitaxial growth from the inside of the reactor to perform cleaning is necessary. Therefore, it is an important problem that adhering materials such as particles adhering to the inner wall of the reactor or surfaces of various members in the furnace are reduced to reduce a maintenance operation for cleaning and improve equipment utilization.

It is an object of the present invention to provide a vapor-phase growth apparatus and a vapor-phase growth method which reduce particle generation and adhering materials in a reactor to make it easy to improve productivity in epitaxial growth of a semiconductor substrate.

A vapor-phase growth apparatus according to an embodiment of the present invention includes a gas supply port formed in an upper portion of a cylindrical reactor, a discharge port formed in a lower portion of the cylindrical reactor, a wafer holding member on which a wafer is placed, and a gas distribution plate arranged between the wafer holding member and the gas supply port, wherein a separation distance between the gas distribution plate and the wafer holding member is set such that a film forming gas to form an epitaxial layer on a wafer is in a laminar flow state on a surface of the wafer on a surface of the wafer holding member.

A vapor-phase growth method according to another embodiment of the present invention uses a vapor-phase growth apparatus which includes a gas supply port formed in an upper portion of a cylindrical reactor, a discharge port formed in a lower portion of the cylindrical reactor, a wafer holding member in which a wafer is placed, and a gas distribution plate arranged between the wafer holding member and the gas supply port. In the vapor-phase growth method which uses the vapor-phase growth apparatus to downward flow a film forming gas from the gas supply port into the reactor through the gas distribution plate to vapor-grow an epitaxial layer, a separation distance between the gas distribution plate and the wafer holding member is set such that a film forming gas to form an epitaxial layer is in a laminar flow state on a surface of the wafer or a surface of the wafer holding member.

### BRIEF DESCRIPTION OF THE DRAWINGS

FIG. 1 is a vertical sectional view showing one configuration of a single-wafer-processing type epitaxial growth apparatus according to an embodiment.

FIG. 2 is a vertical sectional view showing a configuration of a comparative example of the single-wafer-processing type epitaxial growth apparatus.

FIGS. 3A and 3B are pattern diagrams showing a gas flow of a cooling gas in the single-wafer-processing type epitaxial growth apparatus according to the embodiment.

FIG. 4 is a vertical sectional view of a single-wafer-processing type epitaxial growth apparatus for explaining another embodiment.

### DETAILED DESCRIPTION OF THE EMBODIMENTS

Preferred embodiments of the present invention will be described below with reference to the accompanying drawings. Common reference numerals as in the embodiments denote the same or similar parts in the embodiments, and overlapping descriptions are partially omitted.

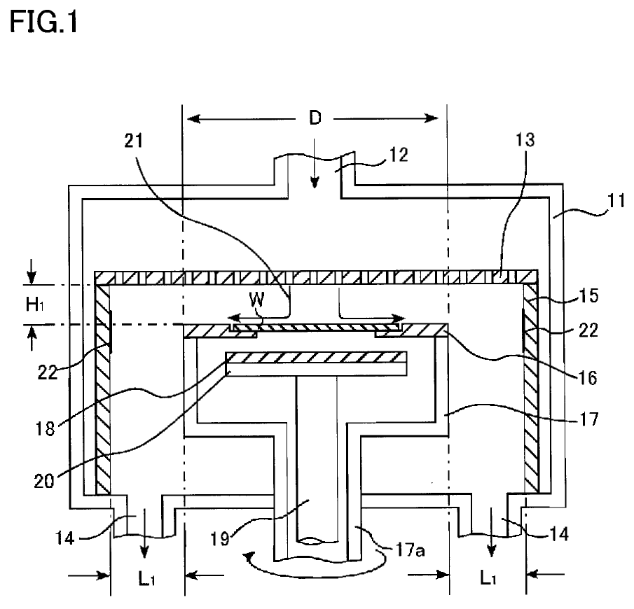

FIG. 1 shows a configuration of a single-wafer-processing type epitaxial growth apparatus according to one embodiment of the present invention. As shown in FIG. 1, the epitaxial growth apparatus includes a cylindrical hollow reactor 11, a gas supply port 12, and a gas distribution plate 13. The cylindrical hollow reactor 11 and is made of, for example, stainless steel. The gas supply port 12 introduces a film forming gas 21 into the reactor 11 from the top of the reactor 11. The gas distribution plate 13 creates laminar flow of the film forming gas 21 introduced from the gas supply port 12 and downstream flows the film forming gas 21 onto a semiconductor wafer W placed downward as, for example, a layered flow. The epitaxial growth apparatus also includes a gas discharge port 14 which discharges a reaction product and a part of the film forming gas obtained after the reaction on the semiconductor wafer W surface or the like from the bottom portion of the reactor 11 to the outside of the reactor 11. A cylindrical liner 15 having a top portion on which the gas distribution plate 13 is arranged and covering the inner wall of the reactor 11 is arranged. The gas discharge port 14 is connected to a vacuum pump (not shown).

The cylindrical liner 15 is an anti-adhesive plate which covers the inner wall of the reactor 11 along the side wall, shields the inner wall from the film forming gas 21 or a reaction product, and prevents the reaction product from being precipitated and deposited on an inner wall of the reactor 11 as an adhering material. In this case, the adhering material is deposited on the inner wall of the cylindrical liner 15 during the epitaxial growth.

A rotator unit 17 and a heater 18 are arranged inside the reactor 11. The rotator unit 17 arranges an annular holder 16 of the wafer holding member to place and hold the semiconductor wafer W on the upper surface and rotates the annular holder 16. The heater 18 heats the semiconductor wafer W placed on the annular holder 16 with radiant heat. In this case, the rotator unit 17 is connected to a rotating device (not shown) having a rotating shaft 17a located thereunder, and the rotator unit 17 is attached so as to be rotatable at a high speed. A diameter of the cylindrical rotator unit 17 is preferably almost equal to an outer diameter of the annular holder 16. The cylindrical rotating shaft 17a is connected to a vacuum pump to exhaust the hollow rotator unit 17, and the semiconductor wafer W may be brought into vacuum contact with the annular holder 16 by the suction. The rotating shaft 17a is rotatably inserted into the bottom portion of the reactor 11 through a vacuum seal member.

The heater 18 is fixed to the upper surface of a support table 20 of a support shaft 19 penetrating the inside of the rotating shaft 17a. For example, a push-up pin (not shown) to attach/detach the semiconductor wafer W to/from the annular holder 16 is formed in the support table 20. As the wafer holding member, a structure which contacts with a substantially entire rear surface of the semiconductor wafer W may be used in place of the annular holder. In this case, since a disk-like wafer substrate is generally placed on the wafer holding member, a planar shape of the edge of the wafer holding member is preferably circular, and the wafer holding member is preferably composed of a material which does not shield the radiant heat from the heater 18.

In the single-wafer-processing type epitaxial growth apparatus, the gas distribution plate 13 is a disk made of, for example, quartz glass and has a large number of gas discharge ports (or holes) formed therein. As shown in FIG. 1, H₁ denotes a separation distance between an upper surface of the annular holder 6 and a lower surface of the gas distribution plate 13 which are parallel arranged to face each other. The separation distance H₁ is set such that the film forming gas 21 to form an epitaxial layer on the semiconductor wafer W is set in a laminar flow state on the surface of the semiconductor wafer W or the surface of the annular holder 16.

Assuming that the outer diameter of the annular holder 16 is D, H₁/D≦⅕ is preferably satisfied as will be described later. In this case, an inner circumference side of the annular holder 16 is counterboared, and the semiconductor wafer W is placed on the counterboard surface such that the rear surface of the semiconductor wafer W is in contact with the counterboared surface. Thus, a major surface of the semiconductor wafer W is located at a level which is almost equal to the level of the major surface of the annular holder 16.

Furthermore, as shown in FIG. 1, an outer diameter of the annular holder 16 is represented by D, and a separation distance between the inner circumference surface of the cylindrical liner 15 and the outer circumference surface of the rotator unit 17 is represented by L₁. As will be described later, 2/15≦L₁/D≦⅓ is preferably satisfied.

A wafer inlet/outlet port and a gate valve to insert or remove the semiconductor wafer W are formed in the single-wafer-processing type epitaxial growth apparatus shown in FIG. 1 at a side-wall portion of the reactor 11 (not shown). The semiconductor wafer W can be conveyed by a handling arm between, for example, a load lock chamber and the reactor 11 which are connected to each other by the gate valve. Since the handling arm made of, for example, synthetic quartz is inserted into a space between the gas distribution plate 13 and the annular holder 16 serving as the wafer holding member, the separation distance H₁ must be equal to or larger than such a size that an insertion space for the handling arm can be secured.

Concrete examples of the separation distance H₁ and the separation distance L₁ will be described below. When the semiconductor wafer W is a silicon wafer having, for example, a diameter of 200 mmφ, the outer diameter D of the annular holder 16 is set to 300 mmφ. When an insertion space required for a conveying operation performed by the handling arm is set to, for example, about 10 mm, a preferable range of the separation distance H₁ is 20 mm to 60 mm. Similarly, under the above conditions, a preferable range of the separation distance L₁ is 40 mm to 100 mm.

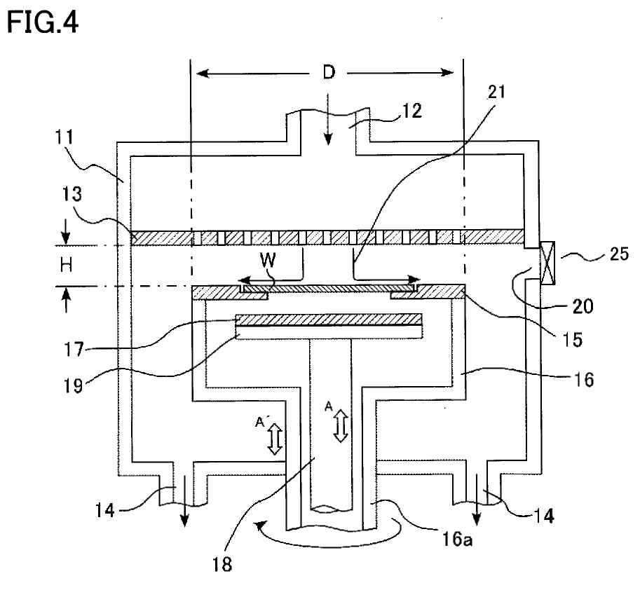

In this case, when the annular holder 16 and the heater 18 are enabled to be vertically moved as described later (see FIG. 4), a distance between the upper surface of the semiconductor wafer W and the lower surface of the gas distribution plate 13 in vapor-phase growth may be about 1 mm. Upon completion of the vapor-phase growth, when the annular holder 16 and the rotator unit 17 are moved downward to set the distance to about 10 mm, a conveying operation of the wafer W by the handling arm can be performed. In this case, when the distance between the semiconductor wafer W surface and the lower surface of the gas distribution plate 13 is lower than 1 mm, the thickness of the vapor-phase-grown film varies, or defects occur. For this reason, the distance between the semiconductor wafer W surface and the lower surface of the gas distribution plate 13 is limited to 1 mm.

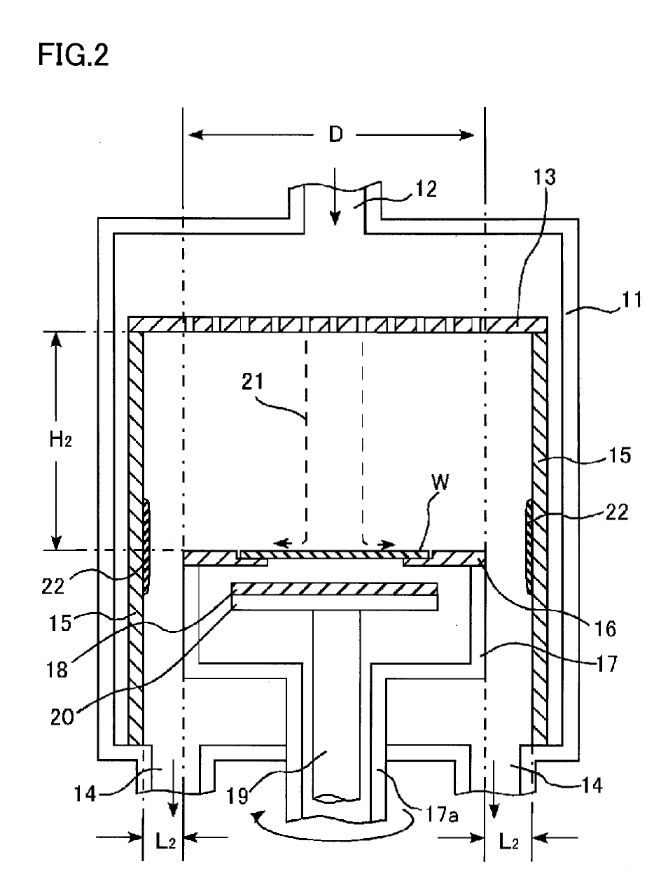

An epitaxial growth method using the single-wafer-processing type epitaxial growth apparatus and an effect in the embodiment will be described below with reference to FIGS. 1 and 2. FIG. 2 is a vertical sectional view showing a configuration of a comparative example of the single-wafer-processing type epitaxial growth apparatus.

The semiconductor wafer W is placed on the annular holder 16 in the reactor 11 by a known single-wafer-processing type scheme. In this case, the gate valve of the wafer inlet/outlet port of the reactor 11 is opened, and the semiconductor wafer in, for example, the load lock chamber is conveyed into the reactor 11 by the handling arm. The semiconductor wafer W is placed on the annular holder 16 by using, for example, a push-up pin (not shown), the handling arm is returned to the load lock chamber, and the gate valve is closed.

A vacuum pump (not shown) is operated to discharge the gas in the reactor 11 from the gas discharge port 14 to obtain a predetermined degree of vacuum. The semiconductor wafer W placed on the annular holder 16 is preliminarily heated to a predetermined temperature by a heater 18. Thereafter, a heating output from the heater 18 is increased to heat the semiconductor wafer W to an epitaxial growth temperature. The discharging by the vacuum pump is continued, and a predetermined film forming gas 21 is supplied from the gas supply port 12 while rotating the annular holder 16 at a predetermined speed, so that an epitaxial layer is grown on the semiconductor wafer W surface at the predetermined degree of vacuum.

For example, when a silicon epitaxial layer is to be grown, the temperature of the preliminary heating is set to a desired temperature falling within the range of 500 to 900° C., and the epitaxial growth temperature is set to a desired temperature falling within the range of 1000 to 1200° C. SiH₄, SiH₂Cl₂, or SiHCl₃ is used as a source gas of the silicon, and B₂H₆, PH₃ or AsH₃ is used as a dopant gas. H₂ is generally used as a carrier gas. These gases serve as film forming gases.

In the reactor 11 in the growth of the silicon epitaxial layer, a desired pressure is set within the range of about 2×10³ Pa (15 Torr) to about 9.3×1 Pa (700 Torr). A rotating speed of the annular holder 16 is set to a desired rotating speed falling within the range of, for example, 300 to 1500 rpm.

In the epitaxial growth, the gas distribution plate 13 and the annular holder 16 according to the embodiment are arranged to satisfy H₁/D≦⅕ when the separation distance H₁ between the gas distribution plate 13 and the annular holder 16 has the relation to the outer diameter D of the annular holder 16 as described above. With this arrangement, a turbulent flow rarely occurs on the semiconductor wafer W with respect to the flow of the film forming gas 21 shown in FIG. 1. The film forming gas 21 which passes through the gas distribution plate 13, is become laminar flow, and flows downward is brought into contact with the major surface of the semiconductor wafer Wand the annular holder 16. Thereafter, the film forming gas 21 is horizontally flow as a laminar flow along the major surface and flows. The horizontal laminar flow of the film forming gas reduces particles adhering to the surface of the semiconductor wafer W, and a high yield of epitaxial layers can be obtained.

The outer circumference surfaces of the cylindrical liner 15 and the rotator unit 17 according to the embodiment are formed to satisfy 2/15≦L₁/D≦⅓ when the separation distance L₁ between the cylindrical liner 15 and the rotator unit 17 has a relation to the outer diameter D of the annular holder 16 as described above. This reduces an adhering material 22 formed by precipitating the film forming gas or a reaction product on the inner wall of the cylindrical liner 15.

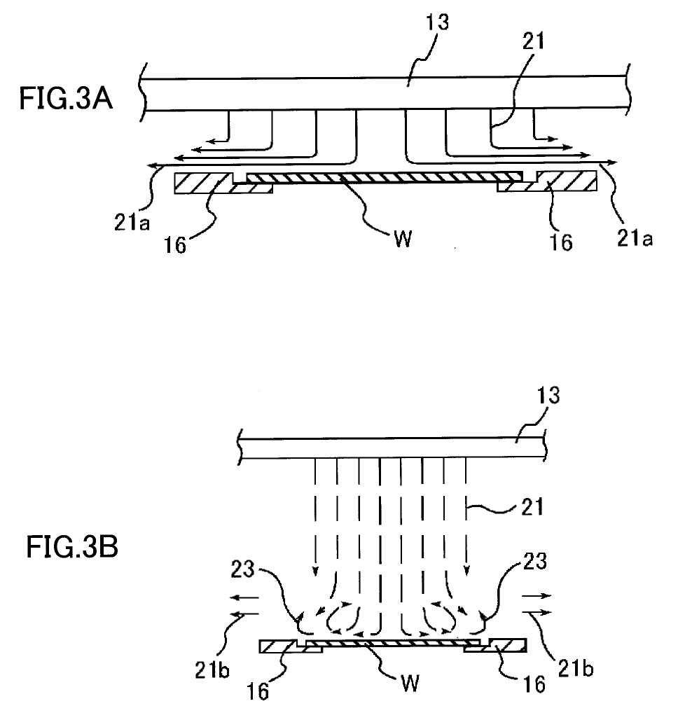

In this case, 2/15≦L₁/D is satisfied, and the separation distance L₁ is made larger than that in a conventional comparative example, so that an adhering material on the inner wall of the cylindrical liner 15 is suppressed from being scattered due to an increase inflow rate of a horizontally flowing gas 21a (FIG. 3A) (will be described later). The film forming gas passing through the upper surface of the semiconductor wafer W and heated or the horizontally flowing gas 21a of the reaction product is easily pushed out toward the gas discharge port 14 by the film forming gas flowing downward from the gas outlet ports (or holes) of the gas distribution plate 13 near the inner wall of the cylindrical liner 15. Thus, the adhering material 22 on the inner wall of the cylindrical liner 15 considerably reduces. The effect increases when L₁/D increases. However, an increase rate of the effect decreases when ⅓<L₁/D is satisfied. If anything, a problem caused by an increase in size of the apparatus by the increase of the separation distance L₁ increases.

A maintenance operation interval for periodical cleaning of the cylindrical liner 15 can be elongated, for example, about twice the maintenance operation interval in a conventional technique. In this manner, since the maintenance operation for the apparatus is considerably reduced, an operation rate of the epitaxial growth apparatus is considerably increased.

In contrast to this, the single-wafer-processing type epitaxial growth apparatus shown in FIG. 2 shows a conventional typical reactor. A separation distance H₂ between the gas distribution plate 13 and the annular holder 16 does not generally satisfy H₂/D≦⅕, because usually H₂/D≧1 in relation to the outer diameter D of the annular holder 16. In this case, the film forming gas 21 once converted to laminar flow rectified by the gas distribution plate 13 easily makes an upward flow in response to radiant heat from the semiconductor wafer W surface heated to a high temperature in epitaxial growth, and the film forming gas 21 partially makes a swirling current on the semiconductor wafer W. The crosscurrent generated in the film forming gas 21 easily precipitates the film forming gas or a reaction product on the semiconductor wafer W, and the crosscurrent makes it easy to adhere the precipitated particles onto the semiconductor wafer W. An yield of epitaxial layers is not easily increased.

In the example in FIG. 2, a separation distance L₂ between the cylindrical liner 15 and the rotator unit 17 satisfies L₁/D< 2/15 in relation to the outer diameter D of the annular holder 16. With this configuration, in comparison with the case using the epitaxial growth apparatus as shown in FIG. 1, the epitaxial growth apparatus according to the embodiment is easily influenced by the radiant heat from the semiconductor wafer W, and the adhering material 22 precipitated on the inner wall of the cylindrical liner 15 increases. An interval between maintenance operations for periodical cleaning of the cylindrical liner 15 becomes short, and an operation rate of the epitaxial growth apparatus is difficult to be improved.

After the epitaxial growth, a decrease in temperature of the semiconductor wafer W on which the epitaxial layer is formed is started. In this case, the supply of the film forming gas and the rotation of the rotator unit 17 are stopped, and while placing the semiconductor wafer W on which the epitaxial layer is formed on the annular holder 16, automatic adjustment is performed such that a heating output from the heater 18 is returned first to decrease the temperature of the semiconductor wafer W to the temperature of the preliminary heating.

In this time, a cooling gas is flowed from the gas supply port 12 into the reactor 11, the semiconductor wafer W is cooled by the cooling gas rectified by the gas distribution plate 13. In this case, the cooling gas may be an H₂ gas which is used as a carrier gas for the film forming gas, or a noble gas such as argon or helium or an N₂ gas may be used. A pressure in the reactor 11 in which the cooling gas is flowed is set to be almost equal to a pressure in growth of the epitaxial layer.

After the semiconductor wafer W is stabilized to a predetermined temperature, the semiconductor wafer W is detached from the annular holder 16 by, for example, the push-up pin. In order to detach the semiconductor wafer W from the annular holder 16, not only the push-up pin, but also an electrostatic attaching scheme or Bernoulli chuck scheme which floats the semiconductor wafer W itself may be used. The gate valve is opened again to insert the handling arm between the gas distribution plate 13 and the annular holder 16, and the semiconductor wafer W is placed on the handling arm. The handling arm on which the semiconductor wafer W is placed is returned to the load lock chamber.

As described above, a film forming cycle of an epitaxial layer to one semiconductor wafer is finished. Subsequently, a film is formed on another semiconductor wafer is performed according to the same process sequence as described above.

In the embodiment, the single-wafer-processing type epitaxial growth apparatus in which the cylindrical liner 15 is arranged along the side wall of the reactor 11 has been described. Even though the cylindrical liner 15 is absent, the same effect as described above can be obtained. In this case, in the maintenance operation for cleaning, an adhering material to be deposited on the side wall portion of the reactor 11 is periodically removed.

With reference to the pattern diagrams in FIGS. 3A and 3B, an operation of an apparatus structure according to the embodiment in epitaxial growth of a semiconductor wafer will be described below. FIGS. 3A and 3B are pattern diagrams showing a gas flow of the film forming gas 21 between the gas distribution plate 13 of the single-wafer-processing type epitaxial growth apparatus and the annular holder 16 which holds the semiconductor wafer W. In this case, FIG. 3A shows a case in which the separation distance H₁ satisfies H₁/D≦⅕ in relation to an outer diameter D (diameter of the wafer holding member) of the annular holder 16, and FIG. 3B shows a case in which the separation distance H₂ satisfies H₂/D>⅕ as described in the comparative example.

The film forming gas 21 in the reactor 11 forms a viscous flow, and the film forming gas 21 is converted to a laminar flow, for example, a layered flow through the gas outlet ports (or holes) of the gas distribution plate 13 and flows downward. In this case, in the configuration as shown in FIG. 3A, the film forming gas 21 which flows downward is brought into the semiconductor wafer W and the major surface of the annular holder 16 to partially react on the surface of the semiconductor wafer W at a high temperature, and an epitaxial layer is formed. An unreacted film forming gas or a reaction product horizontally meanders along the major surface of the annular holder 16 or the like and flows while keeping a laminar flow state. A crosscurrent does not occur at an outer circumference end of the cylindrical liner 15. The flows of the gases are slightly deflected in a rotating direction on a plane parallel to the major surface with pivotal rotation of the rotator unit 17.

Accordingly, precipitation by the film forming gas or the reaction product on the upper portion of the semiconductor wafer W is suppressed. In addition, it has been confirmed by simulation that a flow rate of the horizontally flowing gas 21a according to the embodiment along the major surface is ten times the flow rate of a horizontally flowing gas 21b in a comparative example in FIG. 3B. Thus, even though particles precipitated on the upper portion of the semiconductor wafer W are generated, or even though particles are flown by peeling, scattering, or the like of the adhering material 22 deposited on the inner wall of the cylindrical liner 15, the particles are horizontally discharged by the rectified gas flow, and the particles rarely adhere to the semiconductor wafer W surface. The particles are discharged from the gas discharge port 14 through a gas flow path between the rotator unit 17 and the cylindrical liner 15 which are separated by the separation distance L1.

In contrast to this, the configuration as shown in FIG. 3B causes the laminar flow state of the film forming gas 21 flowing downward to be disturbed on the major surfaces of the semiconductor wafer W and the annular holder 16 and easily broken. Thereafter, the film forming gas 21 is brought into contact with the major surfaces to horizontally meander and flow. As described above, a flow rate of the horizontally flowing gas 21b is smaller than that of the horizontally flowing gas 21a according to the embodiment, and a cross current originally occurs at the outer circumference end of the annular holder 16. For these reasons, the film forming gas 21 disturbed in the laminar flow state and flowing downward very easily generates a swirling current 23 on the outer circumference side of the semiconductor wafer W or on the annular holder 16. When the value H₂/D increases, the swirling current 23 is also generated on a more inner circumference of the semiconductor wafer W.

Due to the generation of the swirling current 23, precipitation by the film forming gas or the reaction product easily occurs in the growth of the epitaxial layer. Therefore, a large number of particles caused by so-called spatial reaction are generated. The crosscurrent such as the swirling current 23 causes the particles precipitated and generated on the upper portion of the semiconductor wafer W or the particles generated by peeling, scattering, or the like of the adhering material 22 deposited on the inner wall of the cylindrical liner 15 to easily adhere to the semiconductor wafer W surface.

Even in gas cooling at the reduced temperature of the semiconductor wafer W after the epitaxial growth, the structure of the apparatus according to the embodiment achieves the following operations and effectively function. Even in explanation of the operation, FIGS. 3A and 3B are used. In this explanation, the film forming gas 21 in FIGS. 3A and 3B is replaced with a cooling gas.

The cooling gas in the reactor 11 forms a viscous flow. The cooling gas is introduced from the gas supply port 12 and converted to a laminar flow, for example, a layered flow through the gas outlet ports (or holes) of the gas distribution plate 13, and flows downward. In this case, in the configuration shown in FIG. 3A, the cooling gas flowing downward is brought into contact with the major surfaces of the semiconductor wafer W and the annular holder 16. Thereafter, the cooling gas horizontally meanders and flows while being kept in a laminar flow state. A crosscurrent does not occur at the outer circumference end of the annular holder 16.

For this reason, in the plane of the semiconductor wafer W, small quantity of cooling gas is in contact with the semiconductor wafer W at a uniform temperature, and heat radiation by heat exchange with the cooling gas is uniformly performed. Heat radiation is not disturbed by occurrence of the crosscurrent at the outer circumference end of the annular holder 16, and the uniformity of the heat radiation is held. In decrease in temperature of the semiconductor wafer W, a temperature in the plane is kept uniform. Heat radiation by thermal radiation from the semiconductor wafer W surface is uniform in the plane.

In contrast to this, the configuration as shown in FIG. 3B causes the laminar flow state of the cooling gas flowing downward to be disturbed on the major surfaces of the semiconductor wafer W and the annular holder 16 and easily broken. Thereafter, the cooling gas is brought into contact with the major surfaces, horizontally meanders, and flows. A crosscurrent at the outer circumference end of the annular holder 16 originally easily occurs. For these reasons, the cooling gas flowing downward in the disturbed laminar flow state very easily generates the swirling current 23 on the outer circumference side of the semiconductor wafer W or on the annular holder 16. With an increase in H₂/D value, the swirling current 23 occurs on a more inner circumference of the semiconductor wafer W.

Due to the generation of the swirling current 23, heat radiation by heat exchange with the cooling gas is ununiformly performed in the plane of the semiconductor wafer W. In a decrease in temperature of the semiconductor wafer W, the uniformity of the in-plane temperature is degraded.

In the embodiment described above, in the epitaxial layer growth for the semiconductor wafer, generation of particles considerably reduces which are caused by precipitating a part of the film forming gas or the reaction product in the space of the reactor, for example, a portion above the semiconductor wafer. A part of the film forming gas reacts on the inner wall of the reactor or the inner wall of the liner and is precipitated, so that the quantity of an adhering material serving as a particle source reduces. For this reason, the particles adhering to the wafer decrease in the epitaxial growth, thereby increasing an yield. A maintenance operation is considerably relieved which removes particles necessarily generated in the epitaxial growth and the adhering material from the inside of the reactor to clean the reactor. In this manner, productivity in the epitaxial growth is improved.

In the embodiment, in the step of decreasing the temperature of a semiconductor wafer to convey the semiconductor wafer out of the reactor, a cooling rate of the semiconductor wafer can be made higher than that in a conventional technique for the above reasons, and a throughput in manufacturing of epitaxial wafers can be easily improved. A decrease in temperature of the semiconductor wafer on which the epitaxial layer has been grown is stable more than that in the conventional technique, and a fluctuation in cooling of the semiconductor wafers becomes small. For this reason, a frequency of occurrence of wafer cracks when the semiconductor wafer is conveyed out to the load lock chamber by the handling arm. In addition to an effect of reducing crystal defects such as slips of the semiconductor wafer, a production yield in film formation of the epitaxial layer is further increased.

FIG. 4 is a diagram showing another embodiment of the invention. In the above embodiment, as shown in FIG. 4, a wafer holding member 16 and a heater 17 are constructed such that the wafer holding member 16 and the heater 17 can be vertically moved (arrows A and A′ in FIG. 4). More specifically, although not shown, drive mechanisms such as air cylinders are arranged at lower end portions of the wafer holding member 16 and the heater 17 such that the wafer holding member 16 and the heater 17 can be cooperatively vertically moved.

In this case, a distance between the gas distribution plate 13 and the semiconductor wafer W can be adjusted to 1 mm to 60 mm by the drive mechanisms of the wafer holding member 16 and the heater 17. Even when the gas distribution plate 13 and the semiconductor wafer W are extremely approximated to each other, i.e., 1 mm, an epitaxial layer can be grown. When the semiconductor wafer W is inserted or removed, the distance between the gas distribution plate 13 and the semiconductor wafer W is preferably set to about 20 mm. The distance may also be set to about 10 mm.

In the embodiment in FIG. 4, the distance between the gas distribution plate 13 and the semiconductor wafer W in the growth is ideally small. Actually, the distance is limited to about 1 mm. When the distance is adjusted to about 1 mm as described above, a susceptor 15 which holds the wafer W and the heater 17 can be cooperatively moved. The gas distribution plate 13 can also be moved.

Vertical movement of the wafer holding member 16 and the heater 17 can also be cooperated with movement of a mechanism which detaches the wafer W from the annular holder 16 to insert or remove the wafer, for example, with movement of a push-up pin.

According to the embodiments of the present invention described above, there are provided a vapor-phase growth apparatus and a vapor-phase growth method which can reduce generation of particles and an adhering material in the reactor in epitaxial growth to make it easy to improve productivity of the epitaxial growth.

The preferable embodiments of the present invention are described above. However, the embodiments do not limit the present invention. A person skilled in the art can variously change and modify the concrete embodiments without departing from the spirit and scope of the present invention.

For example, in the embodiments, the single-wafer-processing type epitaxial growth apparatus may be connected to a conveying chamber of, for example, a cluster tool through a gate valve 25.

As the wafer holding member, not only an annular holder but also a so-called susceptor which has a heating mechanism and which is in contact with the entire rear surface of a semiconductor wafer may be used. When the annular holder (having an opening formed in the intermediate portion) is used, a removal flat plate is arranged on the opening. For example, the flat plate may be lifted up to make it possible to insert or remove a wafer into/from the reactor by a handling arm.

The gas supply port according to the present invention is not formed on not only the top face of the reactor, but also only an upper portion of the entire reactor. For example, the gas supply port may be formed on, for example, the side surface of the reactor. Furthermore, the gas discharge port may be formed on not only the bottom surface of the reactor but also a lower portion of the entire reactor. For example, the gas discharge port may be formed on the side surface of the reactor.

The present invention is similarly applied to a single-wafer-processing type epitaxial growth apparatus having a structure in which a semiconductor wafer to be epitaxially grown is placed on an irrotational wafer holding member.

Although a wafer substrate on which a film is to be formed is typically a silicon wafer, a semiconductor substrate except for a silicon substrate such as a silicon oxide substrate may be used. As a thin film formed on the wafer substrate, a silicon film or a monocrystalline silicon film containing boron, phosphorous, or arsenic is most generally used. A monocrystalline silicon film partially containing a polysilicon film or another thin film, for example, a compound semiconductor film such as a GaAs film or a GaAlAs film can be applied without any problem.

In the present invention, not only epitaxial growth but also general vapor-phase growth, for example, MOCVD may be used. The epitaxial growth apparatus need not be of a single-wafer-processing type.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vapor-phase growth apparatus comprising: a gas supply port formed in an upper portion of a cylindrical reactor; a discharge port formed in a lower portion of the cylindrical reactor; a wafer holding member on which a wafer is placed; and a gas distribution plate arranged between the wafer holding member and the gas supply port, wherein
a separation distance between the gas distribution plate and the wafer holding member is set such that a film forming gas to form an epitaxial layer on the wafer is in a laminar flow state on a surface of the wafer or a surface of the wafer holding member.

2. The apparatus according to claim 1, wherein when the separation distance between the gas distribution plate and the wafer holding member is represented by H and a diameter of the wafer holding member is represented by D, H/D≦⅕ is satisfied.

3. The apparatus according to claim 1, wherein
the wafer holding member is configured to be vertically movable.

4. The apparatus according to claim 3, wherein
a heater to heat the wafer is arranged immediately under the wafer holding member, and the heater is configured to be vertically movable in cooperation with the wafer holding member.

5. The apparatus according to claim 4, wherein
the vertical movements of the wafer holding member and the heater are incorporated with movement of a mechanism which separates the wafer from the wafer holding member in order to remove or insert the wafer.

6. The apparatus according to claim 2, wherein
when a separation distance between a side wall in the reactor and the wafer holding member or a separation distance between a cylindrical anti-adhesive plate arranged to cover the side wall and the wafer holding member is represented by L, 2/15≦L/D≦⅓ is satisfied.

7. The apparatus according to claim 1, wherein
a distance between a lower surface of the gas distribution plate and an upper surface of the wafer holding member can be adjusted to not less than 1 mm and not more than 60 mm.

8. The apparatus according to claim 2, wherein
a handling arm which removes or inserts the wafer from/into the reactor can be inserted between the lower surface of the gas distribution plate and the upper surface of the wafer holding member.

9. The apparatus according to claim 3, wherein
a handling arm which removes or inserts the wafer from/into the reactor can be inserted between the lower surface of the gas distribution plate and the upper surface of the wafer holding member.

10. A vapor-phase growth method which uses a vapor-phase growth apparatus including: a gas supply port formed in an upper portion of a cylindrical reactor; a discharge port formed in a lower portion of the cylindrical reactor; a wafer holding member on which a wafer is placed; and a gas distribution plate arranged between the wafer holding member and the gas supply port to cause a film forming gas to flow downward from the gas supply port in the reactor through the gas distribution plate to vapor-grow an epitaxial layer on the wafer, wherein
a separation distance between the gas distribution plate and the wafer holding member is set such that the film forming gas is in a laminar flow state on a surface of the wafer or a surface of the wafer holding member.

11. The method according to claim 10, wherein
a handing arm to remove or insert the wafer from/into the reactor is arranged between a lower surface of the gas distribution plate and an upper surface of the wafer holding member, and the wafer is removed or inserted from/into the reactor with the movement of the handling arm.

12. The method according to claim 11, wherein
the gas distribution plate and the wafer are approximated to each other when a film is formed on the wafer, and, when the wafer is removed or inserted, the distance between the gas distribution plate and the wafer increases to enable the wafer to be removed or inserted.
